(19) United States
(12) Patent Application Publication
(10) Pub. No.: US 2024/0068084 A1
(43) Pub. Date: Feb. 29, 2024

(54) DEPOSITION APPARATUS

(71) Applicant: Samsung Display Co., LTD., Yongin-si (KR)

(72) Inventors: Jongyoon LEE, Yongin-si (KR); Sok Won NOH, Yongin-si (KR); Junhyeuk KO, Yongin-si (KR)

(21) Appl. No.: 18/239,101

(22) Filed: Aug. 28, 2023

(30) Foreign Application Priority Data
Aug. 29, 2022 (KR) 10-2022-0108312

(51) Int. Cl. C23C 14/24; C23C 14/04

(52) U.S. Cl. CPC C23C 14/24; C23C 14/042; H10K 59/12

(57) ABSTRACT

A deposition apparatus includes: a chamber; a deposition source disposed in the chamber to include nozzles arranged in a first direction; and a deposition angle limiter disposed on the deposition source in the chamber. The deposition angle limiter includes: a low-incident angle limiting plate disposed between adjacent first and second nozzles among the nozzles and spaced apart from the first nozzle by a first height in a height direction intersecting the first direction; and a high-incident angle limiting plate surrounding at least a portion of the first nozzle and spaced apart from the first nozzle by a second height in the height direction. The first nozzle extends in the height direction.

This application claims priority to Korean Patent Application No. 10-2022-0108312, filed on Aug. 29, 2022, and all the benefits accruing therefrom under 35 U.S.C. § 119, the content of which in its entirety is herein incorporated by reference.

### BACKGROUND

### (a) Technical Field

This disclosure relates to a deposition apparatus including a deposition angle limiter.

### (b) Description of the Related Art

An emissive display device is used as a device for displaying an image. The emissive display device may express an image by a combination of pixels, and the pixels may be implemented by a light-emitting device such as a light emitting diode.

The light emitting diode may include an anode, a cathode, and an emission layer therebetween. The emission layer of the light emitting diode may be formed by a deposition method. For example, in a vacuum chamber, emission layers matching a mask pattern may be deposited on a substrate by aligning the substrate on which emission layers are to be formed on a mask in which an opening of a predetermined pattern is formed and allowing a material of the emission layers to pass through the opening of the mask.

The material of the emission layers is vaporized at a deposition source and emitted from the nozzle, allowing it to pass through a number of masks. In this case, particles of the material may be deposited on the substrate with a constant angle while moving in a straight line at a radiated angle. When passing through the opening of the mask, a portion that is not evenly (e.g., of a uniform thickness) deposited on the substrate (i.e., a portion with a non-uniform thickness) may occur due to an incident angle of the particles. This area is called a shadow.

### SUMMARY

It may be advantageous to increase an incident angle of deposition material particles to reduce a shadow area in order to increase a lifetime and efficiency of a light emitting device. Embodiments have been made in an effort to provide a deposition apparatus including a deposition angle limiter capable of increasing an incident angle of deposition material particles deposited on a substrate, preventing particles from accumulating around a nozzle, and improving ejection rate variability of the particles.

A deposition apparatus according to an embodiment includes: a chamber; a deposition source disposed in the chamber to include nozzles arranged in a first direction; and a deposition angle limiter disposed on the deposition source in the chamber. The deposition angle limiter includes: a low-incident angle limiting plate disposed between adjacent first and second nozzles among the nozzles and spaced apart from the first nozzle by a first height in a height direction intersecting the first direction; and a high-incident angle limiting plate surrounding at least a portion of the first nozzle and spaced apart from the first nozzle by a second height in the height direction. The first nozzle extends in the height direction.

The second height may be greater than the first height.

The low-incident angle limiting plate and the high-incident angle limiting plate may have a first length and a second length in a height direction, respectively, and the second length may be shorter than the first length.

The deposition angle limiter may further include an angle limiting plate disposed at opposite sides of the nozzles in a second direction intersecting the first direction and extending in the first direction.

The angle limiting plate may include a first plate and a second plate disposed at a first side and a second side of the nozzles, respectively, in the second direction.

The angle limiting plate, the low-incident angle limiting plate, and the high-incident angle limiting plate may be spaced apart from a center of the first nozzle by a first distance, a second distance, and a third distance in a plan view, respectively. The first distance may be greater than the second distance, and the second distance may be greater than the third distance.

The deposition angle limiter may further include a connector connecting the high-incident angle limiting plate and the low-incident angle limiting plate.

The deposition source may further include a radiation protection plate defining openings therein into which the nozzles are inserted. The low-incident angle limiting plate and the high-incident angle limiting plate may each be spaced apart from the radiation heat protection plate.

The angle limiting plate may be in contact with the radiation heat protection plate.

The high-incident angle limiting plate may include a first portion and a second portion separated along the first direction.

The first portion and the second portion of the high-incident angle limiting plate may each be semi-cylindrical.

The deposition angle limiter may further include an adjacent high-incident angle limiting plate surrounding at least a portion of the second nozzle. The first portion or the second portion may be connected to the adjacent high-incident angle limiting plate by a connector.

The connector may be connected to the low-incident angle limiting plate.

The high-incident angle limiting plate may have a cylindrical shape.

A deposition apparatus according to an embodiment includes: a chamber configured to accommodate a substrate and a mask therein; a deposition source disposed in the chamber and including a first nozzle and a second nozzle arranged in a first direction; and a deposition angle limiter disposed between the deposition source and the mask to control an incident angle of particles emitted from the first nozzle and the second nozzle with respect to a major surface plane of the mask. The deposition angle limiter includes: an angle limiting plate disposed at opposite sides of the first nozzle and the second nozzle in a second direction intersecting the first direction and extending in the first direction; a low-incident angle limiting plate disposed between the first nozzle and the second nozzle to extend in the second direction; and a high-incident angle limiting plate surrounding at least a portion of the first nozzle and disposed closer to a center of the first nozzle than each of the angle limiting plate and the low-incident angle limiting plate.

The low-incident angle limiting plate and the high-incident angle limiting plate may be spaced apart from the nozzle by a first height and a second height, respectively, in a third direction intersecting the first direction and the second direction, and the second height may be greater than the first height.

The low-incident angle limiting plate and the high-incident angle limiting plate may have a first length and a second length in the third direction, respectively, and the second length may be shorter than the first length.

The angle limiting plate may be disposed farther than the low-incident angle limiting plate from a center of the first nozzle in a plan view.

The low-incident angle limiting plate may be connected to the angle limiting plate. The deposition angle limiter may further include a connector connecting the high-incident angle limiting plate and the low-incident angle limiting plate.

The high-incident angle limiting plate may include a first portion and a second portion separated along the first direction, and the first portion and the second portion may each be semi-cylindrical.

According to the embodiments, it is possible to provide a deposition apparatus including a deposition angle limiter capable of increasing an incident angle of deposition material particles deposited on a substrate, preventing particles from accumulating around a nozzle, and effectively improving ejection rate variability of the particles. Further, according to the embodiments, there are other advantageous effects that can be recognized throughout the specification.

### BRIEF DESCRIPTION OF THE DRAWINGS

FIG. 1 schematically illustrates a deposition apparatus according to an embodiment.

FIG. 2 illustrates a schematic exploded perspective view showing a deposition source according to an embodiment.

FIG. 3 illustrates how deposition material particles are deposited on a substrate through an opening through a mask.

FIG. 4 illustrates a schematic top plan view of a deposition angle limiter according to an embodiment.

FIG. 5 illustrates a partially enlarged view of the deposition angle limiter illustrated in FIG. 4.

FIG. 6 illustrates a schematic cross-sectional view taken along line A-A′ of FIG. 5.

FIG. 7 illustrates a cross-sectional view taken along line B-B′ of FIG. 5.

FIG. 8 illustrates a cross-sectional view taken along line C-C′ of FIG. 5.

FIG. 9, FIG. 10, and FIG. 11 each illustrate that particles are filtered by a deposition angle limiter in a deposition apparatus according to an embodiment.

FIG. 12 illustrates that particles are filtered by a deposition angle limiter in a deposition apparatus according to a comparative embodiment.

FIG. 13 illustrates a graph showing a shadow effect in a deposition apparatus according to a comparative embodiment and an embodiment.

FIG. 14 illustrates a schematic top plan view of a deposition angle limiter according to another embodiment.

FIGS. 15A and 15B illustrate side views of a high-incident angle limiting plate according to some embodiments.

FIGS. 16A to 16C illustrate side views of a low-incident angle limiting plate according to some embodiments.

FIG. 17 illustrates a schematic cross-sectional view showing a stacked structure of a display panel according to an embodiment.

### DETAILED DESCRIPTION

This disclosure will be described more fully hereinafter with reference to the accompanying drawings, in which embodiments are shown.

Further, sizes and thicknesses of constituent elements shown in the accompanying drawings are arbitrarily given for better understanding and ease of description.

It will be understood that when an element such as a layer, film, area, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise” and variations such as “comprises” or “comprising” will be understood to imply the inclusion of stated elements but not the exclusion of any other elements.

In addition, in the specification, “connected” means that two or more components are not only directly connected, but two or more components may be connected indirectly through other components, physically connected as well as being electrically connected, or it may be referred to be different names depending on the location or function, but may include connecting each of parts that are substantially integral to each other.

In the drawings, signs “x”, “y”, and “z” are used to indicate directions, wherein x is used for indicating a first direction, y is used for indicating a second direction that is perpendicular to the first direction, and z is used for indicating a third direction that is perpendicular to the first direction and the second direction.

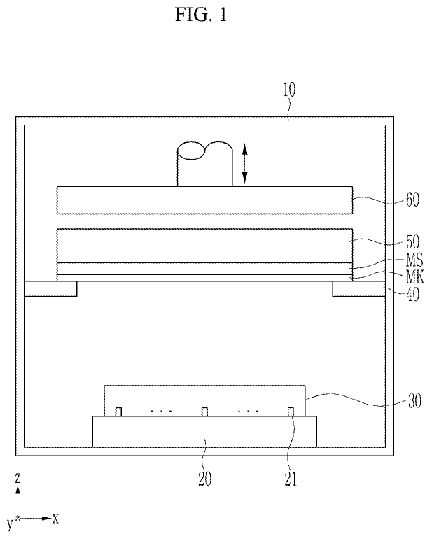

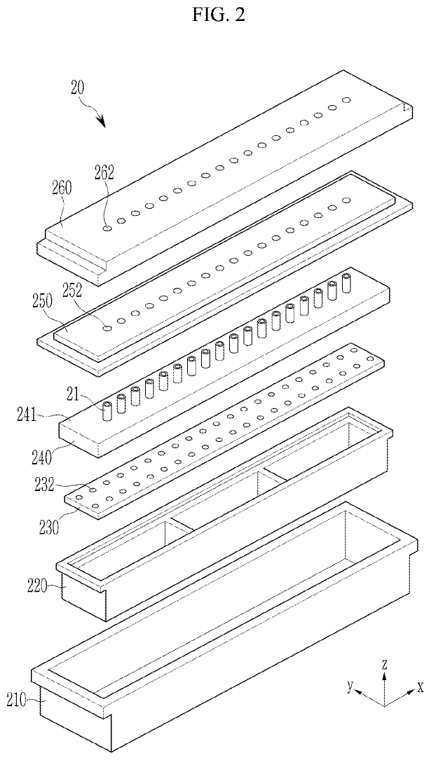

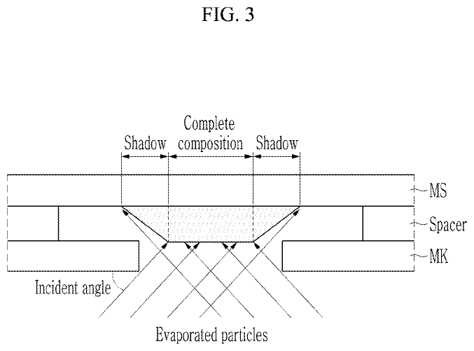

FIG. 1 schematically illustrates a deposition apparatus according to an embodiment, and FIG. 2 illustrates a schematic exploded perspective view showing a deposition source according to an embodiment. FIG. 3 illustrates how deposition material particles are deposited on a substrate through an opening through a mask.

Referring to FIG. 1, a deposition apparatus according to an embodiment may include a chamber 10, a deposition source 20, a deposition angle limiter 30, a holder 40, a cool plate 50, and a magnet assembly 60. The deposition source 20, the holder 40, the cool plate 50, and the magnet assembly 60 may be positioned in the chamber 10.

The chamber 10 may be a vacuum chamber, and an interior of the chamber 10 may be maintained in a vacuum atmosphere or an atmosphere of an inert gas such as nitrogen gas. The chamber 10 may be connected to a vacuum pump (not illustrated) for controlling a pressure therein. Depositing a deposition material on a substrate MS for manufacturing a display panel or the like may be performed in the chamber 10 of the deposition apparatus. The substrate MS may be fixed at a predetermined position inside the chamber 10. A mask MK may be positioned under the substrate MS. The mask MK may be detachably fixed to the holder 40 above the deposition source 20. The mask MK may be a fine metal mask defining an opening therein corresponding to a pattern of a layer to be formed on the substrate MS. Since the mask MK is positioned between the deposition source 20 and the substrate MS, the deposition material may be deposited on the substrate MS in a predetermined pattern. The chamber 10 may include an inlet (not illustrated) for carrying the substrate MS, the mask MK, and the like in and out.

The deposition source 20 may store and evaporate a deposition material (e.g., material in an emission layer of an emissive display device). The deposition source 20 may spray the deposition material toward the substrate MS to be deposited. The deposition source 20 may be a linear deposition source. The deposition source 20 may have a length in a first direction x and a width in a second direction y, and the length may be greater than the width. The deposition source 20 may include nozzles 21 for emitting material particles. The nozzles 21 may be arranged in a line or a plurality of columns along the first direction x at an upper portion of the deposition source 20.

Referring to FIG. 2, in more detail, the deposition source 20 may include a heater unit 210, a crucible 220, an inner plate 230, a nozzle unit 240, a heat conduction plate 250, a radiation protection plate 260, and the like. The heater unit 210 may heat the crucible 220 to evaporate the deposition material in the crucible 220. The crucible 220 may store deposition data and an upper portion thereof may be exposed. The crucible 220 may have a longitudinal side extending in the first direction x. The inner plate 230 may be positioned at the upper portion of the crucible 220, and may define openings 232 therein. The inner plate 230 may allow the material evaporated from the crucible 220 to be uniformly dispersed and introduced into the nozzles 21. The inner plate 230 may be mounted on a clasp formed in the crucible 220. The nozzle unit 240 may include a nozzle plate 241 and nozzles 21 protruding from the nozzle plate 241 in the third direction z. The nozzles 21 may be arranged in the first direction x, and thus the deposition source 20 may be a linear deposition source. The heat conduction plate 250 may define openings 252 therein corresponding to the nozzles 21, and the nozzles 21 may be inserted into the openings 252. As heat is transferred through the heat conduction plate 250, the nozzles 21 may have a uniform temperature, and thus deposition material particles evaporated in the crucible 220 may be uniformly emitted to the chamber 10 through the nozzles 21. The heat conduction plate 250 may be referred to as an upper plate. The radiation protection plate 260 may cover the nozzle unit 240, and may define openings 262 therein into which the nozzles 21 are inserted. The radiation protection plate 260 may suppress heat generated by the heater unit 210 from being dissipated into the chamber 10, and accordingly, it is possible to prevent the heat emitted from the high-temperature heater unit 210 and the crucible 220 from affecting a deposition film or damaging a structure inside the chamber 10. The radiation protection plate 260 may form an overall appearance of the deposition source 20 together with the heater unit 210. The radiation protection plate 260 may define an upper surface of the deposition source 20. The radiation protection plate 260 may be referred to as a reflector or a base plate.

The deposition angle limiter 30 may be positioned over the deposition source 20. The deposition angle limiter 30 may allow an incident angle of particles emitted from the nozzles 21 toward the substrate MS through the opening of the mask MK to be greater than or equal to a predetermined angle. Here, the incident angle is measured with respect to a major surface plane (i.e., x-y plane) of the substrate MS or the mask MK as shown in FIG. 3. For example, the deposition angle limiter 30 may restrict particles having an incident angle that is smaller than a predetermined angle from reaching the mask MK and the substrate MS. Referring to FIG. 3, since a shadow area becomes wider as an incident angle decreases, and increasing the incident angle may reduce the shadow area and may improve deposition quality. A spray angle of the nozzle may be improved by improving a shape of the nozzles, thereby increasing the incident angle. However, since particle density around the nozzles is high, it may be difficult to increase the incident angle above a predetermined angle only by improving the nozzle shape. Particles emitted from the nozzles 21 at a low-incident angle may be blocked by positioning the deposition angle limiter 30, thereby increasing the incident angle. A detailed configuration of the deposition angle limiter 30 will be described later.

A magnet assembly 60 may be positioned on the substrate MS in order to attach the mask MK to the substrate MS. The magnet assembly 60 may include magnets (not illustrated) and a yoke plate (not illustrated) supporting the magnets.

The mask MK may be pulled toward the magnet assembly 60 by a magnetic force of the magnets of the magnet assembly 60, and the mask MK may be attached to and closely adhered to the substrate MS. Accordingly, a lifting phenomenon between the mask MK and the substrate MS may be improved, and a shadow effect may be improved during a deposition process. The magnet assembly 60 may be provided to move up and down in a third direction z, and the deposition apparatus may include an actuator for lifting and lowering the magnet assembly 60.

The cool plate 50 may be positioned between the substrate MS and the magnet assembly 60 to press the substrate MS with its own weight, and may improve adhesion between the substrate MS and the mask MK. The cool plate 50 may be a non-magnetic material in order to not affect the magnetic force of the magnet assembly 60.

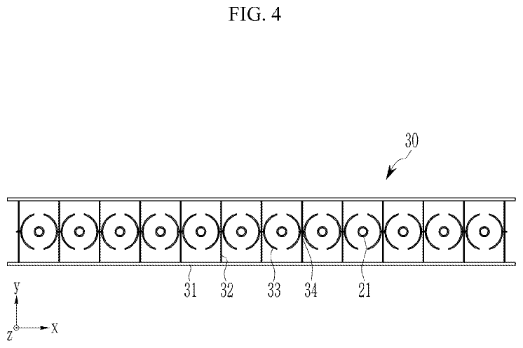

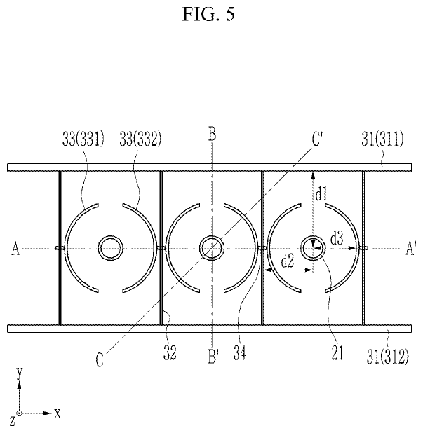

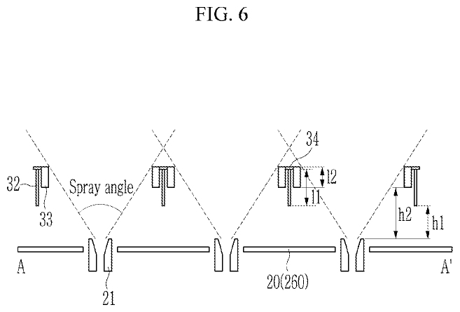

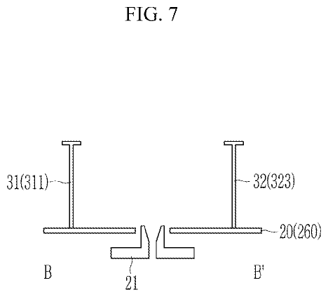

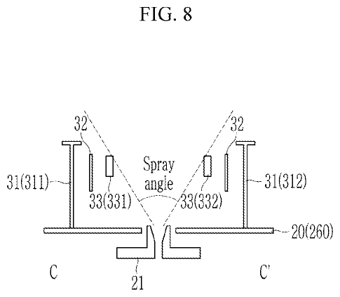

FIG. 4 illustrates a schematic top plan view of a deposition angle limiter according to an embodiment, FIG. 5 illustrates a partially enlarged view of the deposition angle limiter illustrated in FIG. 4, FIG. 6 illustrates a schematic cross-sectional view taken along line A-A′ of FIG. 5, FIG. 7 illustrates a cross-sectional view taken along line B-B′ of FIG. 5, and FIG. 8 illustrates a cross-sectional view taken along line C-C′ of FIG. 5. Here, the top plan view is a view in a third direction z.

Referring to FIG. 4, FIG. 5, FIG. 6, FIG. 7, and FIG. 8, the deposition angle limiter 30 includes an angle limiting plate 31, a low-incident angle limiting plate 32, a high-incident angle limiting plate 33, and a connector 34.

The angle limiting plate 31 may be elongated in the first direction x at a first side and a second side along a row of the nozzles 21. The angle limiting plate 31 may be positioned perpendicular to an x-y plane. The angle limiting plate 31 may limit movement of particles with a relatively low-incident angle among particles emitted from the nozzles 21. The angle limiting plate 31 may be positioned above the deposition source 20, and a lower end portion thereof in the third direction z may be in contact with the deposition source 20. For example, when an uppermost portion of the deposition source 20 is the radiation protection plate 260, a lower end portion of the angle limiting plate 31 may contact the radiation protection plate 260. The angle limiting plate 31 may support a low-incident angle limiting plate 32 and a high-incident angle limiting plate 33.

The angle limiting plate 31 may include a first plate 311 and a second plate 312 positioned at a first side and a second side of the nozzles 21, respectively. The first plate 311 and the second plate 312 may each be rectangular when viewed from the front (i.e., view in the second direction y). The first plate 311 and the second plate 312 may each have a plate shape approximately parallel to an x-z plane. The first plate 311 and the second plate 312 may be spaced apart from the nozzles 21 by a same distance. For example, in a plan view, the first plate 311 and the second plate 312 may be spaced apart from a center of each of the nozzles 21 by a first distance d1 in the second direction y. The first plate 311 and the second plate 312 may be spaced apart from the nozzles 21 by different distances in another embodiment.

The low-incident angle limiting plate 32 (or referred to as a first incident angle limiting plate) may be positioned at opposite sides of each nozzle 21 in the first direction x, and may be provided in a plurality. The low-incident angle limiting plate 32 may be positioned between adjacent nozzles 21, and may extend in the second direction y. The low-incident angle limiting plate 32 may be positioned perpendicular to an x-y plane. The low-incident angle limiting plate 32 may limit movement of particles with a relatively low-incident angle among particles emitted from the respective nozzles 21. The low-incident angle limiting plate 32 may be connected to the angle limiting plate 31. For example, the low-incident angle limiting plate 32 may be welded to the angle limiting plate 31. The low-incident angle limiting plate 32 may be integrally formed with the angle limiting plate 31. The low-incident angle limiting plate 32 may form a flat shape such as a ladder together with the angle limiting plate 31.

The low-incident angle limiting plate 32 may be positioned apart from the nozzles 21 by a first height h1 in the third direction z. The third direction z is a direction in which the nozzle 21 extends. The third direction z is referred to as “height direction.” The low-incident angle limiting plate 32 may have a first length 11 in the third direction z, and the first length 11 may correspond to a difference between a height of an upper end and a lower end of the low-incident angle limiting plate 32. The low-incident angle limiting plate 32 may not be in contact with the deposition source 20. For example, when an uppermost portion of the deposition source 20 is the radiation protection plate 260, a lower end portion of the low-incident angle limiting plate 32 may be spaced apart from the radiation protection plate 260 in the third direction z. The low-incident angle limiting plate 32 may be rectangular when viewed from a side (i.e., view in the first direction x). The low-incident angle limiting plate 32 may have a plate shape approximately parallel to a y-z plane. The low-incident angle limiting plates 32 positioned at opposite sides of one nozzle 21 in the first direction x may be spaced apart from the nozzle 21 by a same distance. For example, in a plan view, the low-incident angle limiting plates 32 may be spaced apart from a center of each of the nozzles 21 by a second distance d2 in the first direction x. The second distance d2 may be smaller than the first distance d1. The low-incident angle limiting plates 32 positioned at opposite sides of one nozzle 21 in the first direction x may be spaced apart from the nozzle 21 by different distances in another embodiment.

The high-incident angle limiting plate 33 (or referred to as a second incident angle limiting plate) may be positioned to surround each nozzle 21. The high-incident angle limiting plate 33 may be positioned between adjacent low-incident angle limiting plates 32. The high-incident angle limiting plate 33 may be positioned perpendicular to an x-y plane. The high-incident angle limiting plate 33 may limit movement of particles with a relatively high-incident angle among particles emitted from the nozzles 21. In addition, the high-incident angle limiting plate 33 may limit movement of relatively low incidence particles among the particles emitted from the adjacent nozzle 21. The high-incident angle limiting plate 33 may have a plate shape curved with a predetermined curvature radius.

The high-incident angle limiting plate 33 may be positioned apart from the nozzles 21 by a second height h2 in the third direction z. The second height h2 may be greater than the first height h1. That is, the high-incident angle limiting plate 33 may be positioned further away from the nozzles 21 in the third direction z than the low-incident angle limiting plate 32. The high-incident angle limiting plate 33 may have a second length 12 in the third direction z, and the second length 12 may correspond to a difference between a height of an upper end and a lower end of the low-incident angle limiting plate 32. The second length 12 may be smaller than the first length 11. In a plan view, the high-incident angle limiting plates 33 may be spaced apart from a center of the nozzle 21 by a third distance d3. The third distance d3 may be smaller than the second distance d2. In a plan view, the high-incident angle limiting plate 33 may draw a circle having the third distance d3 as a radius thereof from a center of the nozzle 21. The high-incident angle limiting plate 33 may be divided into two portions. That is, the high-incident angle limiting plate 33 may include a first portion 331 and a second portion 332 positioned at a first side and a second side of the nozzle 21 in the first direction x, respectively. The first portion 331 and the second portion 332 may be separated along the first direction x. The first portion 331 and the second portion 332 may each be approximately semi-cylindrical.

The high-incident angle limiting plate 33 may be connected to the low-incident angle limiting plate 32 through the connector 34. For example, the high-incident angle limiting plate 33 may be welded to the connector 34, and the connector 34 may be welded to the low-incident angle limiting plate 32. The second portion 332 of one high-incident angle limiting plate 33 may be connected to the first portion 331 of the adjacent high-incident angle limiting plate 33 through the connector 34. That is, the connector 34 may connect the first portion 331 and the second portion 332 of the high-incident angle limiting plate 33 which are adjacent in the first direction x. The connector 34 may be connected to an upper end of the low-incident angle limiting plate 32. Accordingly, the high-incident angle limiting plate 33 may be positioned as if it spans the upper end of the low-incident angle limiting plate 32 through the connector 34.

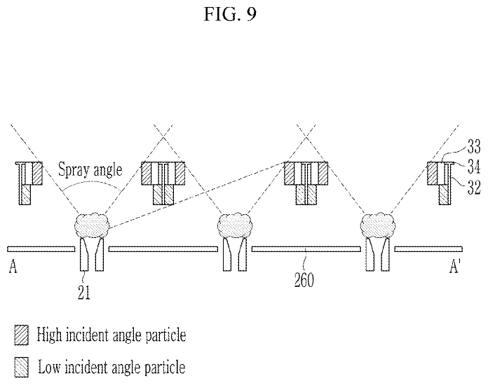

FIG. 9, FIG. 10, and FIG. 11 each illustrate that particles are filtered by a deposition angle limiter in a deposition apparatus according to an embodiment. FIG. 9, FIG. 10, and FIG. 11 may correspond to FIG. 6, FIG. 7, and FIG. 9, respectively.

Referring to FIG. 9, FIG. 10, and FIG. 11, particles evaporated from the crucible 220 of the deposition source 20 and emitted through the nozzle 21 may be sprayed from the nozzle 21 at a predetermined spray angle. Here, the spray angle indicates a maximum angle of the emitted direction of the particles with respect to the intended direction (i.e., third direction z). Particles sprayed from the nozzle 21 may have a mean value of free path (i.e., maximum length of a projection of the particles) of several tens of centimeters (cm) to several meters (m) in the vacuum chamber 10, and most may move in a straight line (i.e., third direction z). However, since density of particles around the nozzle 21 is high, the mean value of the free path is relatively short, such that a collision probability between the particles may be greatly increased. Thus, the particles may be sprayed at an angle that is greater than a nozzle surface angle. Here, the nozzle surface angle is a surface angle of an end part of the nozzle with respect to the straight line (i.e., third direction z). In this case, such high-incident particles may be filtered by the high-incident angle limiting plate 33 surrounding the nozzle 21, and such low-incident angle particles may be filtered by the low-incident angle limiting plate 32 and the angle limiting plate 31 positioned at opposite sides of the nozzle 21 in the second direction y. Here, the high-incident particles mean particles of which incident angle is in a range so as to be filtered by adjacent high-incident angle limiting plates 33, and the low-incident particles mean particles of which incident angle is in a range so as to be filtered by adjacent low-incident angle limiting plates 32 and angle limiting plates 31. The low-incident angle limiting plate 32 is separated from the nozzle 21 by the first height h1 in the third direction z, and thus particles having an incident angle that is smaller than the low incidence particles may not be filtered by the low-incident angle limiting plate 32 adjacent to the nozzle 21. However, as illustrated in FIG. 9, such particles not filtered by the low-incident angle limiting plate 32 may pass under the low-incident angle limiting plate 32 and be filtered by the high-incident angle limiting plate 33 surrounding the adjacent nozzle 21 and the low-incident angle limiting plate 32 connected thereto or the angle limiting plate 31. Accordingly, only particles with an incident angle that is greater than the high-incident particles (i.e., high-incident particles filtered by the high-incident angle limiting plate 33) may pass through the deposition angle limiter 30 to be deposited on the substrate MS, thereby reducing the shadow area.

The particles filtered by the angle limiting plate 31, the low-incident angle limiting plate 32, and the high-incident angle limiting plate 33 may be deposited on the angle limiting plate 31, the low-incident angle limiting plate 32, and the high-incident angle limiting plate 33. However, the angle limiting plate 31, the low-incident angle limiting plate 32, and the high-incident angle limiting plate 33 are relatively far apart from the nozzle 21, thereby preventing material accumulation around the nozzle 21. When such material accumulation around the nozzle 21 occurs, a volume of a spraying area around the nozzle 21 may be reduced, which may increase variability of a spraying rate of the particles. As in an embodiment, it is possible to improve particle ejection rate variability while reducing the shadow area by designing and positioning the deposition angle limiter 30. Meanwhile, the angle limiting plate 31, the low-incident angle limiting plate 32 and/or the high-incident angle limiting plate 33 may be in the form of a mesh in order to prevent the particles deposited on the deposition angle limiter 30 from accumulating and falling. For example, the angle limiting plate 31, the low-incident angle limiting plate 32, and/or the high-incident angle limiting plate 33 may be formed of a wire mesh such as a woven wire mesh or a welded wire mesh.

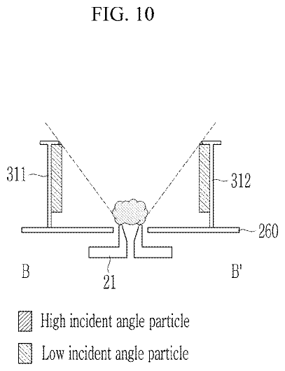

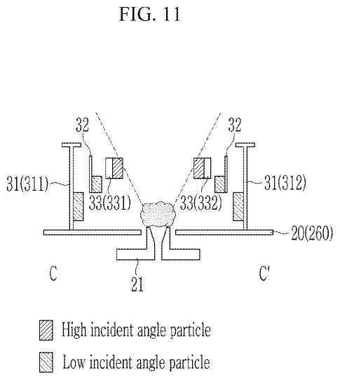

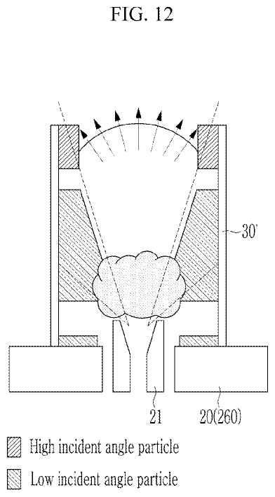

FIG. 12 illustrates that particles are filtered by a deposition angle limiter in a deposition apparatus according to a comparative embodiment.

Referring to FIG. 12, an example of controlling an incident angle of particles by positioning a barrel-shaped deposition angle limiter 30′ to surround the nozzle 21 is illustrated. Only high-incident angle particles among the particles sprayed from the nozzle 21 may pass through the deposition angle limiter 30′ by reducing a width (diameter) of the deposition angle limiter 30′ or increasing a height of an upper end of the deposition angle limiter 30′. The deposition angle limiter 30′ of this structure may be useful for reducing the shadow region by allowing only high-incident angle particles to be deposited. However, particles filtered by the deposition angle limiter 30′ may accumulate inside the deposition angle limiter 30′. Particularly, the deposition angle limiter 30′ is positioned to not be spaced apart or hardly spaced apart from the deposition source in the third direction z, and thus low-incident angle particles may be accumulated around the nozzle. Accordingly, when used for a long time, the material accumulated thereinside may grow and block the nozzle 21. In addition, as a spray area around the nozzle 21 is reduced, a spray rate of the particles may be seriously fluctuated. Accordingly, it may be difficult to apply the deposition angle limiter 30′ to a mass production line that requires long-term operation.

In the deposition angle limiter 30 according to an embodiment, a lower end of the high-incident angle limiting plate 33 positioned relatively close to the nozzle 21 is spaced apart from the deposition source 20 in the third direction z, and the low-incident angle limiting plate 32 is also spaced apart from the deposition source 20 in the third direction z. Accordingly, a vicinity of the nozzle 21 may not be substantially blocked by the high-incident angle limiting plate 33 or the low-incident angle limiting plate 32. Accordingly, a large number of particles sprayed at a low-incident angle may be deposited on the angle limiting plate 31, which may be positioned several times farther from the nozzle 21 than the deposition angle limiter 30′ in the form of a barrel, and it may be accumulated on the low-incident angle limiting plate 32 spaced apart from the nozzle 21 or the high-incident angle limiting plate 33 positioned farther than the low-incident angle limiting plate 32 from the nozzle 21. The low-incident particles may be accumulated over a large area and dispersed to the high-incidence angle limiting plate 33 of the adjacent nozzle 21, thereby preventing nozzle clogging due to material accumulation or growth around the nozzle. In addition, there is no reduction in a spray area volume due to material accumulation or growth in the spray area around the nozzle, and thus a variation of the spray rate of the particles may be reduced.

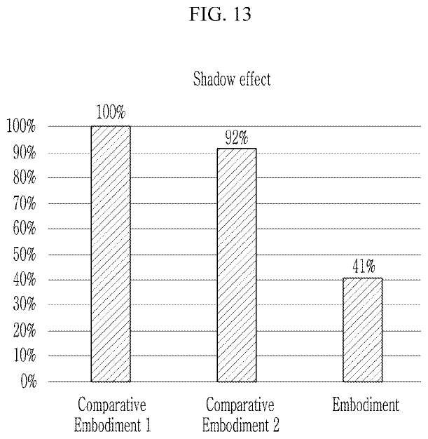

FIG. 13 illustrates a graph showing a shadow effect in a deposition apparatus according to a comparative embodiment and an embodiment.

Referring to FIG. 13, Comparative Embodiment 1 and Comparative Embodiment 2 exhibit a shadow effect during deposition without an angle limiter. Comparative Embodiment 1 shows a result of deposition using an evaporation source including a nozzle having a cylindrical cross-section, and Comparative Embodiment 2 shows a result of deposition using an evaporation source including a nozzle having a Y-shaped cross-section. The embodiment shows a result of deposition by using a deposition source including a nozzle having a Y-shaped cross-section and disposing a deposition angle limiter thereon. Referring to Comparative Embodiments 1 and 2, it was found that a shadow effect was improved by about 8% by changing the cross-sectional shape of the nozzle. That is, the Y-type nozzle is a high-incident angle nozzle capable of increasing an incident angle compared to the cylindrical nozzle. The embodiment showed that the shadow effect was improved by about 51% compared to Comparative Embodiment 2. As described above, it can be seen that there is a limit to reducing the shadow area only by changing the shape of the nozzle, and it is remarkably improved by applying the angle limiter according to the embodiment.

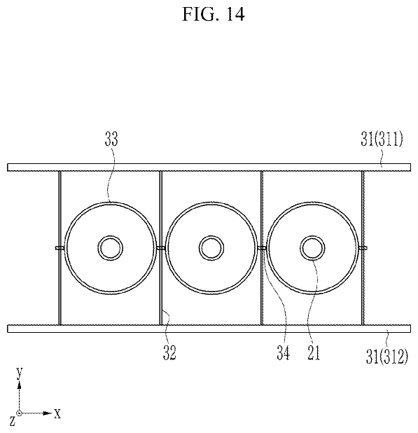

FIG. 14 illustrates a schematic top plan view of a deposition angle limiter according to another embodiment.

Referring to FIG. 14, there is a difference in the shape of the high-incident angle limiting plate 33 compared to the embodiment of FIG. 5. The high-incident angle limiting plate 33 surrounding the nozzle 21 may not be divided into two portions, and may have a single cylindrical shape. Although the high-incident angle limiting plate 33 according to the embodiment of FIG. 5 is opened in the second direction y, the high-incident angle limiting plate 33 according to the present embodiment completely surrounds the nozzle 21. Accordingly, the high-incident angle limiting plate 33 may block particles having an incident angle that is smaller than a predetermined incident angle in all radial directions of the nozzle 21. Each deposited material has different characteristics, and thus a planar shape of the high-incident angle limiting plate 33 may be appropriately changed depending on the material.

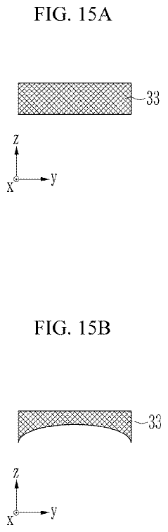

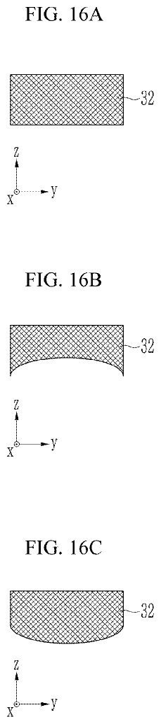

FIGS. 15A and 15B illustrate side views of a high-incident angle limiting plate according to some embodiments, and FIGS. 16A to 16C illustrate side views of a low-incident angle limiting plate according to some embodiments.

Referring to FIGS. 15A and 15B, when the high-incident angle limiting plate 33 is viewed from the side (i.e., view in the first direction x), it may have various shapes, such as an approximately rectangular shape (FIG. 15A), an approximately arcuate shape (FIG. 15B), or the like. Referring to FIGS. 16A to 16C, when the low-incident angle limiting plate 32 is viewed from the side (i.e., view in the first direction x), it may have various shapes such as an approximately rectangular shape (FIG. 16A), an approximately arcuate shape (FIG. 16B), an approximately half-moon shape (FIG. 16C), or the like. When an area of a side surface that can block movement of particles of a deposition material is large, a number of particles accumulated on the low-incident angle limiting plate 32 or the high-incident angle limiting plate 33 increases, and when the area of the side surface is narrow, the number of the particles accumulated on the low-incident angle limiting plate 32 or the high-incident angle limiting plate 33 is reduced. For example, when the high-incident angle limiting plate 33 is formed in an arcuate shape and the low-incident angle limiting plate 32 is formed in a half-moon shape, it is possible to reduce the number of particles accumulated on the high-incident angle limiting plate 33 and to increase the number of particles to accumulate on the low-incident angle limiting plate 32. Since characteristics of each deposited material are different, shapes of the low-incident angle limiting plate 32 and the high-incident angle limiting plate 33 may be changed and various combinations may be used to optimize control of an incident angle of the particles.

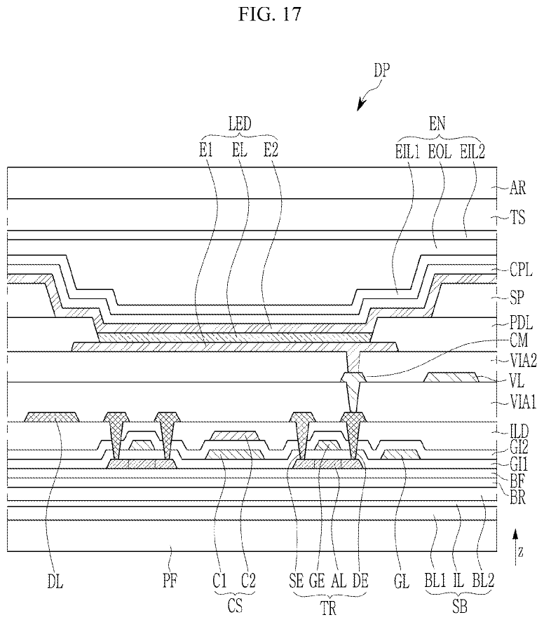

FIG. 17 illustrates a schematic cross-sectional view showing a stacked structure of a display panel according to an embodiment. The cross-section illustrated in FIG. 17 may correspond to approximately one pixel area.

Referring to FIG. 17, the display panel DP, which may include layers that may be formed using the above-described deposition apparatus, basically includes a substrate SB, a transistor TR formed on the substrate SB, and a light emitting diode LED connected to the transistor TR. The light emitting diode LED may correspond to the pixel.

The substrate SB may be a flexible substrate SB capable of bending, folding, rolling, or the like. The substrate SB may be a multilayer including a first base layer BL1, an inorganic layer IL, and a second base layer BL2. The first base layer BL1 and the second base layer BL2 may each include a polymer resin such as polyimide, polyamide, or polyethylene terephthalate.

A barrier layer BR that prevents moisture and oxygen from penetrating the substrate SB may be disposed. The buffer layer BR may include an inorganic insulating material such as a silicon nitride (SiNₓ), a silicon oxide (SiOₓ), and a silicon oxynitride (SiOₓN_{y}), and may be a single layer or multiple layers.

A buffer layer BF may be disposed on the barrier layer BR. The buffer layer BF may improve a characteristic of the semiconductor layer by blocking impurities from the substrate SB when the semiconductor layer is formed, and may flatten a surface of the substrate SB to relieve a stress of the semiconductor layer. The buffer layer BF may include an inorganic insulating material such as a silicon nitride, a silicon oxide, and a silicon oxynitride, and may be a single layer or multiple layers. The buffer layer BF may include amorphous silicon (a-Si).

A semiconductor layer AL of a transistor TR may be disposed on the buffer layer BF. The semiconductor layer AL may include a first region and a second region, and a channel region therebetween. The semiconductor layer AL may include any one of amorphous silicon, polysilicon, and an oxide semiconductor. The oxide semiconductor may include at least one of zinc (Zn), indium (In), gallium (Ga), or tin (Sn). For example, the semiconductor layer AL may include a low-temperature polycrystalline silicon (“LTPS”) or indium-gallium-zinc oxide (“IGZO”).

A first gate insulating layer GI1 may be disposed on the semiconductor layer AL. The first gate insulating layer GI1 may include an inorganic insulating material such as a silicon nitride, a silicon oxide, and a silicon oxynitride, and may be a single layer or multiple layers.

The first gate conductive layer, which may include a gate electrode GE of the transistor TR, a gate line GL, and a first electrode C1 of a storage capacitor CS, may be disposed on the first gate insulating layer GI1. The first gate conductive layer may include molybdenum (Mo), aluminum (Al), copper (Cu), titanium (Ti), or the like, and may be a single layer or multiple layers.

A second gate insulating layer GI2 may be disposed on the first gate conductive layer. The second gate insulating layer GI2 may include an inorganic insulating material such as a silicon nitride, a silicon oxide, and a silicon oxynitride, and may be a single layer or multiple layers.

A second gate conductive layer that may include a second electrode C2 of the storage capacitor CS or the like may be disposed on the second gate insulating layer GI2. The second gate conductive layer may include molybdenum (Mo), aluminum (Al), copper (Cu), titanium (Ti), or the like, and may be a single layer or multiple layers.

An interlayer insulating layer ILD may be disposed on the second gate insulating layer GI2 and the second gate conductive layer. The interlayer insulating layer ILD may include an inorganic insulating material such as a silicon nitride, a silicon oxide, and a silicon oxynitride, and may be a single layer or multiple layers.

A first data conductive layer that may include a first electrode SE and a second electrode DE, a data line DL, and the like of the transistor TR may be disposed on the interlayer insulating layer ILD. The first electrode SE and the second electrode DE may be connected to a first region and a second region of the semiconductor layer AL, respectively, through contact holes of the insulating layers GI1, GI2, and ILD. One of the first electrode SE and the second electrode DE may serve as a source electrode, and the other may serve as a drain electrode. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), or the like, and may be a single layer or multiple layers.

A first planarization layer VIA1 may be disposed on the first data conductive layer. The first planarization layer VIA1 may contain a general purpose polymer such as a polymer derivative having a phenolic group, an acrylic polymer, an imide-based polymer (e.g., a polyimide), and an organic insulating material such as a siloxane-based polymer.

A second data conductive layer, which may include a voltage line VL, a connecting member CM, and the like, may be disposed on the first planarization layer VIAL The voltage line VL may transfer voltages such as a driving voltage, a common voltage, an initialization voltage, and a reference voltage. The connecting member CM may be connected to the second electrode DE of the transistor IR through a contact hole of the first planarization layer VIAL The second data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), or the like, and may be a single layer or multiple layers.

A second planarization layer VIA2 may be disposed on the second data conductive layer. The second planarization layer VIA2 may contain an organic insulating material such as a general purpose polymer such as poly(methyl methacrylate) or styrene, a polymer derivative having a phenolic group, an acrylic polymer, an imide-based polymer, and a siloxane-based polymer.

A first electrode E1 of the light emitting diode LED is disposed on the second planarization layer VIA2. The first electrode E1 may be referred to as a pixel electrode. The first electrode E1 may be connected to the connecting member CM through a contact hole formed in the second planarization layer VIA2. Accordingly, the first electrode E1 may be electrically connected to the second electrode DE of the transistor TR to receive a driving current for controlling luminance of the light emitting diode LED. The transistor TR to which the first electrode E1 is connected may be a driving transistor or a transistor that is electrically connected to the driving transistor. The first electrode E1 may be formed of a reflective conductive material or a translucent conductive material, or may be formed of a transparent conductive material. The first electrode E1 may include a transparent conductive material such as an indium tin oxide (“ITO”) or an indium zinc oxide (“IZO”). The first electrode E1 may include a metal such as lithium (Li), calcium (Ca), aluminum (Al), silver (Ag), magnesium (Mg), or gold (Au), or a metal alloy.

A pixel defining layer PDL may be positioned on the second planarization layer VIA2 and the first electrode E1. The pixel defining layer PDL may be referred to as a bank or a partition wall, and may define an opening therein overlapping the first electrode E1 in a top plan view. The pixel defining layer PDL may include an organic insulating material, e.g., a general purpose polymer such as poly(methyl methacrylate) or polystyrene, a polymer derivative having a phenolic group, an acrylic polymer, an imide-based polymer, and a siloxane-based polymer.

A spacer SP may be positioned on the pixel defining layer PDL. The spacer SP include an organic insulating material such as an acryl-based polymer, an imide-based polymer, and an amide-based polymer.

An emission layer EL of the light emitting diode LED may be disposed on the first electrode E1. The emission layer EL may be formed using the above-described deposition apparatus. In addition to the emission layer EL, a functional layer including at least one of a hole injection layer, a hole transport layer, an electron transport layer, and an electron injection layer may be disposed on the first electrode E1.

A second electrode E2 of the light emitting diode LED is disposed on the emission layer EL. The second electrode E2 may be referred to as a common electrode. The second electrode E2 may be made of a low work function metal such as calcium (Ca), barium (Ba), magnesium (Mg), aluminum (Al), silver (Ag), or a metal alloy, as a thin layer to have light transmittance. The second electrode E2 may include a transparent conductive oxide such as an indium tin oxide (ITO) or an indium zinc oxide (IZO).

The first electrode E1, the emission layer EL, and the second electrode E2 of each pixel may constitute a light emitting diode LED, such as an organic light emitting diode. The first electrode E1 may serve as an anode, and the second electrode E2 may serve as a cathode. An emission region of the light emitting diode LED may correspond to a pixel.

A capping layer CPL may be disposed on the second electrode E2. The capping CPL may improve light efficiency by adjusting a refractive index. The capping layer CPL may be disposed to entirely cover the second electrode E2. The capping layer CPL may include an organic insulating material, or may include an inorganic insulating material.

An encapsulation layer EN may be disposed on the capping layer CPL. The encapsulation layer EN may encapsulate a light emitting diode LED to prevent moisture or oxygen from penetrating from the outside. The encapsulation layer EN may be a thin film encapsulation layer in which the organic layer EOL is positioned between the first inorganic layer EIL1 and the second inorganic layer EIL2.

A touch sensor layer TS including touch electrodes may be disposed on the encapsulation layer EN. An anti-reflection layer AR for reducing external light reflection may be disposed on the touch sensor layer TS.

A protective film PF may be positioned under the substrate SB. The protective film PF may protect the display panel DP in a manufacturing process of the display device. The protective film PF may include a polymer such as polyethylene terephthalate, a silicone-based polymer (e.g., polydimethylsiloxane) and an elastomer (e.g., elastomeric polyurethane).

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus comprising:
a chamber;
a deposition source disposed in the chamber and including nozzles arranged in a first direction; and
a deposition angle limiter disposed on the deposition source in the chamber,
wherein the deposition angle limiter includes:
a low-incident angle limiting plate disposed between adjacent first and second nozzles among the nozzles and spaced apart from the first nozzle by a first height in a height direction intersecting the first direction; and
a high-incident angle limiting plate surrounding at least a portion of the first nozzle and spaced apart from the first nozzle by a second height in the height direction,
wherein the first nozzle extends in the height direction.

2. The deposition apparatus of claim 1, wherein
the second height is greater than the first height.

3. The deposition apparatus of claim 1, wherein
the low-incident angle limiting plate and the high-incident angle limiting plate have a first length and a second length in the height direction, respectively, and the second length is shorter than the first length.

4. The deposition apparatus of claim 1, wherein
the deposition angle limiter further includes an angle limiting plate disposed at opposite sides of the nozzles in a second direction intersecting the first direction and extending in the first direction.

5. The deposition apparatus of claim 4, wherein
The angle limiting plate includes a first plate and a second plate disposed at a first side and a second side of the nozzles, respectively, in the second direction.

6. The deposition apparatus of claim 4, wherein
the angle limiting plate, the low-incident angle limiting plate, and the high-incident angle limiting plate are spaced apart from a center of the first nozzle by a first distance, a second distance, and a third distance in a plan view, respectively,
the first distance is greater than the second distance, and the second distance is greater than the third distance.

7. The deposition apparatus of claim 4, wherein
the deposition angle limiter further includes a connector connecting the high-incident angle limiting plate and the low-incident angle limiting plate.

8. The deposition apparatus of claim 4, wherein
the deposition source further includes a radiation protection plate defining openings therein into which the nozzles are inserted, and
the low-incident angle limiting plate and the high-incident angle limiting plate each are spaced apart from the radiation heat protection plate.

9. The deposition apparatus of claim 8, wherein
the angle limiting plate is in contact with the radiation heat protection plate.

10. The deposition apparatus of claim 1, wherein
the high-incident angle limiting plate includes a first portion and a second portion separated along the first direction.

11. The deposition apparatus of claim 10, wherein
the first portion and the second portion of the high-incident angle limiting plate are each semi-cylindrical.

12. The deposition apparatus of claim 11, wherein
the deposition angle limiter further includes an adjacent high-incident angle limiting plate surrounding at least a portion of the second nozzle, and
the first portion or the second portion is connected to the adjacent high-incident angle limiting plate by a connector.

13. The deposition apparatus of claim 12, wherein
the connector is connected to the low-incident angle limiting plate.

14. The deposition apparatus of claim 1, wherein
the high-incident angle limiting plate has a cylindrical shape.

15. A deposition apparatus comprising:
a chamber configured to accommodate a substrate and a mask therein;
a deposition source disposed in the chamber and including a first nozzle and a second nozzle arranged in a first direction; and
a deposition angle limiter disposed between the deposition source and the mask to control an incident angle of particles emitted from the first nozzle and the second nozzle with respect to a major surface plane of the mask,
wherein the deposition angle limiter includes:
an angle limiting plate disposed at opposite sides of the first nozzle and the second nozzle in a second direction intersecting the first direction and extending in the first direction;
a low-incident angle limiting plate disposed between the first nozzle and the second nozzle to extend in the second direction; and
a high-incident angle limiting plate surrounding at least a portion of the first nozzle and disposed closer to a center of the first nozzle than each of the angle limiting plate and the low-incident angle limiting plate.

16. The deposition apparatus of claim 15, wherein
the low-incident angle limiting plate and the high-incident angle limiting plate are spaced apart from the nozzle by a first height and a second height, respectively, in a third direction intersecting the first direction and the second direction, and
the second height is greater than the first height.

17. The deposition apparatus of claim 16, wherein
the low-incident angle limiting plate and the high-incident angle limiting plate have a first length and a second length, respectively, in the third direction, and
the second length is shorter than the first length.

18. The deposition apparatus of claim 15, wherein
the angle limiting plate is disposed farther than the low-incident angle limiting plate from a center of the first nozzle in a plan view.

19. The deposition apparatus of claim 15, wherein
the low-incident angle limiting plate is connected to the angle limiting plate, and
the deposition angle limiter further includes a connector connecting the high-incident angle limiting plate and the low-incident angle limiting plate.

20. The deposition apparatus of claim 15, wherein
the high-incident angle limiting plate includes a first portion and a second portion separated along the first direction, and the first portion and the second portion are each semi-cylindrical.
